(19) United States
(12) Patent Application Publication
(10) Pub. No.: US 2013/0042910 A1
(43) Pub. Date: Feb. 21, 2013

(54) SOLAR CELL

(71) Applicant: Andrew Archibald Ronald Watt, Oxford (GB)

(72) Inventor: Andrew Archibald Ronald Watt, Oxford (GB)

(73) Assignee: ISIS INNOVATION LTD, Oxford Oxfordshire (GB)

(21) Appl. No.: 13/522,395

(22) PCT Filed: Jan. 14, 2011
(86) PCT No.: PCT/GB2011/000043

§ 371 Date: Sep. 20, 2012

(30) Foreign Application Priority Data
Jan. 15, 2010 (GB) 1000693.0

(51) Int. Cl. H01L 31/032; H01L 31/0368; H01L 31/0224; H01L 31/18

(52) U.S. Cl. 136/256; 438/85; 136/252; 136/265; 136/258; 257/E31.11

(57) ABSTRACT

The present invention provides a solar cell comprising an anode (12) and a cathode (11) with a photosensitive layer (14) therebetween, wherein the photosensitive layer is at most 1000 nm thick and comprises crystalline lead oxide as a photosensitive material, wherein the lead oxide is doped with antimony and/or indium.

### INTRODUCTION

The present invention relates to the field of photovoltaic materials and more particularly to a solar cell, a process for making a solar cell and a method for recycling a solar cell.

### BACKGROUND

Modern solar cells can be classified into one of three generations. Cells from the first generation consist of costly, energy intensive (in production), large-area, high quality single junction devices. Second generation cells rely on thin-film technologies and materials that have been developed to reduce the costs involved, but have reduced efficiencies because of the defects inherent in the lower quality processing methods. Third generation technologies aim to provide enhanced performance while maintaining very low production costs.

The leading second generation thin-film solar cells comprise copper indium gallium diselenide (CIGS-CIS) and cadmium telluride. U.S. Pat. No. 5,464,939 discloses one such thin-film solar cell. Significant market penetration of these systems is hampered by their toxicity and their use of expensive rare earth metals. There is, therefore, a need to develop new second generation thin-film photovoltaic materials which are robust, have a low production energy cost and lower toxicity and are recyclable. Metal oxides composed of titanium and zinc have been the cornerstones of excitonic solar cell technologies for more than a decade where they play an electronic rather than photoactive role.

The photoelectric behaviour of a number of binary compounds having metal cations and non-metal anions, for example, oxides of manganese, iron, copper and lead, is disclosed in U.S. Pat. No. 2,883,305. The photoelectric properties of amorphous lead dioxide are explored in U.S. Pat. No. 4,173,497.

Accordingly, there is a desire for a solar cell and a process for making it that improves upon known cells and processes, or at least mitigates some, or all, of the problems associated with the prior art.

### STATEMENT OF THE INVENTION

In a first aspect, the present invention provides a solar cell comprising an anode and a cathode with a photosensitive layer therebetween, wherein the photosensitive layer is at most 1000 nm thick and comprises crystalline lead oxide as a photosensitive material, wherein the lead oxide is doped with antimony and/or indium.

The present invention provides a solar cell. Solar cells, which are sometimes referred to as photovoltaic or photosensitive cells, are wide area electronic devices that convert solar energy into electricity by the photovoltaic effect. The present invention, therefore, discloses a device for the conversion of sunlight and/or other light sources into electricity. The preferred embodiment of the solar cell is that of a so-called second generation solar cell and, accordingly, the solar cell of the present invention is particularly suitable for large area electricity generation by using assemblies of cells to form solar arrays.

In the following passages different aspects/embodiments of the invention are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The term ‘photosensitive material’ indicates that it absorbs photons. When this happens electrons-hole pairs are created as the electrons are excited. Lead oxides have a suitable band gap for absorbing a portion of the incident photons from visible light. For example, the red form of Pb₃O₄ has a band gap of 2.1-2.2 eV. This theoretically gives a maximum potential power conversion efficiency of around 20%. Photons of lower energy than the band gap either pass straight through, reflect off the surface, or are absorbed to produce heat. Photons of a higher energy may be absorbed and the excess energy converted into heat. Excess heat energy in the material tends to increase the resistance of the material and this reduces the efficiency of electron/hole transport. The band gap selection is therefore a balance between being narrow enough to absorb sufficient photons and broad enough that not too much heat-derived resistance is produced. The present inventors have found that the band gap of In or Sb doped lead oxide is particularly suitable for absorbing photons from visible light.

The photosensitive layer comprises crystalline doped lead oxide as a photosensitive material. The term ‘lead oxide’ as used herein includes all stoichiometries of the binary composition of lead and oxygen doped with In and/or Sb. Common lead oxides which may be used in the present invention once doped include PbO, PbO₂, Pb₂O₃, Pb₃O₄ and Pb₁₂O₁₉ and various oxygen deficient or oxygen rich stoichiometries thereof. The specific composition can be determined by conventional elemental analysis techniques. PbO₂ generally exhibits metallic properties but can be used in a semiconducting oxygen-deficient or doped form.

Preferably the lead oxide is of the empirical formula Pb₁₋ₓSb_{y}O, Pb₁₋ₓIn_{z}O, or Pb₁₋ₓSb_{y′}In_{z′}), wherein x, y, z and (y′+z′) are independently from 0.5 to 0.01. Preferably each of x, y, z and (y′+z′) is independently from 0.30 to 0.01, more preferably from 0.20 to 0.01, still more preferably from 0.15 to 0.05, and most preferably about 0.1. For the avoidance of doubt, (y′+z′) is the sum of y′ and z′. The ratio of y′ to z′ in (y′+z′) is preferably between 5:1 and 1:5, more preferably between 2:1 and 1:2 and most preferably about 1:1, for example, y′ and z′ are each 0.05 when (y′+z′) is 0.1.

The ratio of x to y, z or (y′+z′) is preferably from 0.75 to 1.25. More preferably the ratio is from 0.95 to 1.05 and most preferably it is about 1. That is, the amount of lead that is deficient from the structure has been substituted by indium, antimony or a combination of indium and antimony.

The indium and or antimony doped into the structure may be substitutionally introduced into the lead oxide structure in place of lead. Alternatively, or in combination, the indium and antimony may adopt interstitial positions. This depends on the given structure of the lead oxide. Accordingly, the term “doping” as used herein is to cover both substitutional and/or interstitial introduction of indium and/or antimony into the structure.

The degree of doping may vary across the thickness of the photosensitive layer. In a preferred embodiment the doping is increased in the regions close to the electrode contacts.

The photosensitive layer may further comprise at least one further metal oxide selected from a zinc oxide and/or a titanium oxide. This can be mixed with so as to interpenetrate the lead oxide or, alternatively, the lead oxide may form a discrete layer.

FIG. 2 a) shows a diagram of the geometry of a solar cell according to the present invention, wherein the photosensitive layer comprises a discrete (doped) lead oxide layer and a layer comprising zinc oxide.

FIG. 2 b) shows a diagram of the geometry of a solar cell according to the present invention, wherein the photosensitive layer comprises mixed and interpenetrating (doped) lead oxide layer and zinc oxide.

The zinc oxide and/or a titanium oxide act as electron acceptors from the LUMO of the lead oxide. That is, they have a similar energy LUMO to that of the lead oxide. Furthermore, the LUMO is preferably slightly lower in energy i.e. higher energy required to dissociate the electron. FIG. 3 demonstrates a suitable energy level arrangement. The advantage of using one or more further metal oxide as described above, is that the cell becomes a so-called mixed metal oxide heterojunction cell. The electrons produced in the photosensitive material can be transferred to the LUMO of the one or more further metal oxides which, if it is of lower energy, essentially traps the electron and prevents the electron returning to the lead oxide to quench a hole. Similarly the benefits of a higher energy anode help trap the holes that are produced.

The at least one further metal oxide can be in a discrete layer within the photosensitive layer, such that the photosensitive layer comprises a lead oxide layer and one or more layers comprised of the at least one further metal oxide. Alternatively, in a preferred embodiment, the lead oxide is mixed with and interpenetrates the at least one further metal oxide. In this way, once the electron-hole pair has been formed the electron can be transferred to the electron acceptor and conducted to the cathode. In the embodiment with greater mixing and interpenetration of the crystalline lead oxide and at least one further metal oxide the short distance between electron-hole pair formation sites and the acceptor material helps to prevent unwanted electron-hole quenching before they reach their respective electrodes.

In a solar cell comprising both lead oxide and at least one further metal oxide, the ratio of the lead oxide to the at least one further metal oxide is preferably from 20:1 to 1:20. The ratio is more preferably from 5:1 to 1:5. If there is too little lead oxide in the layer than the efficiency of the solar cell is reduced due to minimal photon absorption.

When the lead oxide forms a discrete layer it is preferred that the layer is formed directly on the anode. Alternatively, or in addition, it can be formed directly on the cathode. The photosensitive layer is preferably in direct contact with at least one of, and preferably both of, the anode and the cathode. However, in another embodiment, one or more further layers may be introduced or formed between the photosensitive layer and one or both of the anode or cathode. Suitable layers for introduction are those known in the art for use in solar cells, such as buffer layers or further conductive layers. Indeed, inefficient electron-hole recombination can be minimised by the introduction of electron/hole blocking layers at the anode/cathode. Furthermore, coatings can be applied to the external surface of the solar cell such as anti-reflection coatings or protective layers. These are common and known in the art.

In the solar cell of the present invention the photosensitive layer is at most 1000 nm thick. The photosensitive layer is preferably a thin film. The photosensitive layer preferably has a thickness of 500 nm or less, preferably 250 nm or less, and most preferably from 100 to 1 nm. In a preferred embodiment the film is between 10 and 200 nm or more preferably 50 and 150 nm thick.

It has been observed that the thickness of the photosensitive layer affects the performance of the cell. The nature of the photosensitive layer and its ability to absorb photons influences the desired thickness of the layer; a poor absorber tends to be used in a thicker layer in order to absorb more photons. At the same time it is advantageous to have a thin layer in order to minimise the amount of photosensitive material required and hence to reduce the cost. Surprisingly it has been discovered that crystalline lead oxide can be used as a photosensitive layer when applied as a thin photosensitive layer, i.e. 500 nm or less. The thin layer of lead oxide also provides a benefit in that the produced electron/hole is less likely to be quenched before it reaches the respective cathode/anode between which it is sandwiched.

The thickness of the photosensitive layer can be determined by microscopy, surface profilometry (Dektak), scanning probe microscopy (SPM) techniques such as atomic force microscopy, and ellipsometry or other such techniques that are known in the art. Alternatively, depending on the technique by which the photosensitive layer is formed, it may be possible to calculate the thickness of the layer by using a fixed amount of the layer-forming material. For example, when applying the layer by spluttering it is possible to calculate the expected layer thickness based on the amount of lead oxide applied per unit area. The thickness is measured between the uppermost and the lowermost surface of the photosensitive layer in a direction perpendicular to the plane of the photosensitive layer. In an embodiment wherein the photosensitive layer is formed directly on the anode, the direction is also perpendicular to the plane of the anode.

The crystalline lead oxide may be polycrystalline or mono-crystalline. The term ‘crystalline’ encompasses predominantly single crystal structures and/or polycrystalline structures and/or structures in between. Crystalline materials are solids in which the constituent atoms, molecules, or ions are packed in a regularly ordered, repeating pattern extending in all three spatial dimensions. A polycrystal is a material that is made of multiple smaller crystals with varying orientation. The variation in direction can be random or directed, possibly due to growth and processing conditions. In contrast, if the lead oxide does not exhibit this regular structure or structures then it is amorphous lead oxide.

It is preferred that the lead oxide layer comprises no more than 20% amorphous lead oxide, more preferably less than 10% and most preferably less than 5%. Ideally there is substantially no amorphous lead oxide in the photosensitive layer. The amount of amorphous lead oxide present can be determined by quantitative X-ray diffraction, transmission electron microscopy for a qualitative view or other such techniques that are known in the art.

When the crystalline lead oxide is polycrystalline it is preferred that the crystallites have a mean crystal diameter of from 1 to 1000 nm, preferably from 10 to 500 nm, more preferably from 10 to 200 nm and most preferably from 20 to 100 nm. Information on the crystal size, shape and size dispersion can be determined by X-ray diffraction, transmission electron microscopy or other such techniques that are known in the art.

It has surprisingly been discovered that the more crystalline the structure of the lead oxide the more effective the lead oxide is as a photosensitive material. Accordingly, a single crystal layer is preferred. Where this is not possible, in order to minimise the interlayer boundaries and, therefore, to improve the efficiency, it is preferred that the polycrystal structure exhibits a crystal size that corresponds to the depth of the photosensitive layer.

The inventors have discovered that the crystalline lead oxide may be polymorphic. That is, the lead oxide crystals of the photosensitive layer may comprise crystals of differing crystal structure. In particular, the crystals may have the same or similar stoichiometry of constituent elements but a different physical structure. The inventors have found that using polymorphic lead oxide as the photosensitive layer allows broadband light absorption with a transmission window in the visible. Accordingly, in a preferred embodiment it is possible to provide a transparent solar cell by providing transparent or thin (i.e. a wire mesh) electrodes as described herein.

Furthermore, for a polycrystalline structure, it is preferred that the standard deviation from the nanometre scale crystal size is less than 100, more preferably less than 20, more preferably less than 5 and most preferably less than 1. It has been discovered that the more regular the crystal structure the greater and more reliable the efficiency.

The ratio of lead atoms to oxygen atoms in the lead oxide of the photosensitive layer is preferably from 0.5 to 0.99:1, and more preferably is from 0.55 to 0.75:1. According to one embodiment the lead oxide essentially comprises doped Minium (Pb₃O₄). That is, the ratio of Pb to O is 0.75:1.

Preferably at least one of the anode and the cathode is substantially transparent to visible light and preferably comprises a doped metal oxide. Suitable doped metal oxides include aluminium doped zinc oxide and/or indium tin oxide as preferred embodiments. Preferably at least one of the anode and the cathode comprises aluminium, platinum, gold, palladium, copper or silver, or an alloy comprising any thereof, most preferably aluminium. Accordingly, in a most preferred embodiment, one of the anode and the cathode is aluminium and the other is substantially transparent to visible light.

The solar cell of the present invention provides a number of surprising benefits over the solar cells known in the art. The use of a thin layer of crystalline doped lead oxide is surprisingly efficient in respect of the amount and cost of material required to the electrical yield. The lead oxide layer is cheap (for example, it is cheaper than titanium oxide), has enhanced stability, easy to work with in manufacture, attractive (due to the colour of the band gap: Pb₃O₄ is red, PbO is yellow and Pb₁₂O₁₉ is brown), less toxic than other alternatives (such as indium-containing cells), recyclable and hence sustainable. Furthermore, the crystalline doped lead oxide in a thin-film provides surprising minority carrier mobility properties. Accordingly, the electron/hole pairs are more likely to reach the cathode/anode before being quenched and the cell exhibits a greater efficiency.

In a second aspect, the present invention provides a process for manufacturing a solar cell comprising a first electrode, a photosensitive layer and a second electrode, arranged in that order, said process comprising:
providing a first electrode having a surface;
forming a photosensitive layer on the surface of the first electrode that is at most 1000 nm thick and comprises crystalline lead oxide, doped with indium and/or antimony, as a photosensitive material; and
providing a second electrode thereon.

The first and second electrodes form the cathode and anode of the solar cell. In a conventional electrolytic cell the anode is the electrode at which electrons leave the cell and oxidation occurs, and the cathode as the electrode at which electrons enter the cell and reduction occurs. However, in a solar cell, which is a form of diode, the anode is where electrons flow into the cell. The cathode is where electrons leave the cell.

In the device of the present invention the anode and cathode are determined by the energy level of the available conduction band in the electrodes. This is demonstrated by FIG. 3. The energy level of the LUMO of PbO is closest matched to the fluorinated tin oxide (FTO). The HOMO is closest matched to the platinum. Therefore, when an electron-hole pair is created the electron moves to the FTO and the hole to the Pt. This makes the Pt the anode and the FTO the cathode.

In order to allow light to be absorbed by the photosensitive layer it is preferred that at least one of the anode and the cathode is substantially transparent to visible light. This may be by the selection of a conductive material that is transparent to visible light. In another embodiment the anode/cathode can be formed from a thin mesh or equivalent of conductive wires so that light can pass between. Preferably it is the cathode that is transparent. Preferred transparent conducting materials comprise aluminium doped zinc oxide and/or indium tin oxide (ITO).

The anode is preferably a surface comprising aluminium, platinum, copper, gold, palladium or silver, or an alloy comprising any thereof. It is most preferred that it is made of aluminium since this can advantageously result in the formation of a Schottky type interface with the photosensitive layer. It would be understood by one in the art that, should materials be selected having suitable energy levels that correspond to those of the lead oxide in the photosensitive layer, then it may be possible to use a transparent anode and have a cathode comprising one or more of the above metals.

Preferably the photosensitive layer is formed by providing a precursor layer of lead and indium and/or antimony on a surface of the first electrode and then contacting the precursor layer with a source of oxygen. The precursor layer may be formed by depositing the metals simultaneously or sequentially in any order.

The photosensitive layer may be formed by vapour deposition, electrodeposition, thermal evaporation, ion plating, reactive sputtering or the application of a sol-gel/colloidal nanoparticle paint.

Preferably the photosensitive layer comprises at least one further metal oxide selected from a zinc oxide and/or a titanium oxide. This is described in more detail in relation to the solar cell of the first aspect.

In this embodiment of the process of the present invention a layer of conductive material is provided as the anode. This may optionally be provided on top of a substrate such as glass, plastic or a paper/card. The conductive material may be provided by any technique known in the art. The photosensitive layer is then applied by sequential vapour deposition of lead oxide and dopant, and then zinc oxide. Then a thin layer of a transparent conductive material is applied to the uppermost surface of the photosensitive layer. Finally an optional antireflective/protective (transparent) layer may be applied on top (as may be done in all embodiments herein).

According to a third aspect of the present invention there is provided a method of recycling the solar cell of the present invention, the method comprising dissolving lead oxide from the cell in ethyl acetate and removing precipitated lead acetate. This allows the removal of precipitated lead acetate. This surprisingly simple method of recycling helps to address one of the major problems with conventional solar cells with their difficult and energetically demanding recycling requirements. Before the treatment is applied the solar cell may be pre-treated by any known method such as chemical or physical degradation, e.g. fragmentation.

According to a fourth aspect, the present invention provides the use of crystalline lead oxide doped with antimony or indium as a photosensitive material in a solar cell to produce electricity. Preferably the lead oxide is of the formula Pb₁₋ₓSbₓO or Pb₁₋ₓInₓO, and wherein x is from 0.25 to 0.01.

The efficiency of the solar cell of the present invention is at least 0.01%. Preferably the efficiency is at least 0.1%, more preferably 1% or 5% and most preferably 10 to 20%. Ideally the efficiency of the cell approaches or exceeds 20% and is at least 10%. The cell may be used over a large area that experiences even weak solar radiation. The cheap manufacturing costs and material costs allow for the use of lead oxide solar cells in industrial solar arrays of more than 10 m², or 100 m² or more, preferably 500 m² or more. As an alternative use, the solar panels of the present invention can be used on satellites or other space-faring vehicles or devices as a primary or secondary power source. The solar cell of the present invention could also be combined with systems for generating hydrogen from water, to produce the gas as a transportable commodity. Due to the high Z of lead, the structure of the cell of the present invention lends itself to applications as a radiation detector as well.

### FIGURES

The present invention will now be described further with reference to the accompanying drawings provided by way of example, in which:

FIG. 1 is a diagram showing the geometry of a solar cell of the present invention. The labels refer to: 11 an Aluminium Cathode; 12 an ITO layer; 13 a glass substrate; and 14 a lead oxide layer.

FIG. 2 a) shows a diagram of the geometry of a solar cell according to the present invention, wherein the photosensitive layer comprises a discrete (doped) lead oxide layer and a layer comprising zinc oxide. The labels refer to: 21 an Cathode; 22 an Anode; 23 light; 24 is a label for the darker shading corresponding to PBO (doped) layer; and 25 is a label for the lighter shading corresponding to ZnO.

FIG. 2 b) shows a diagram of the geometry of a solar cell according to the present invention, wherein the photosensitive layer comprises mixed and interpenetrating (doped) lead oxide layer and zinc oxide. The labels refer to: 21 an Cathode; 22 an Anode; 23 light; 24 is a label for the darker shading corresponding to PBO (doped) layer; and 25 is a label for the lighter shading corresponding to ZnO.

FIG. 3 shows a simplified theoretical schematic of the energy levels in a solar cell having a photosensitive layer comprising lead oxide and zinc oxide. The lead oxide acts as a photosensitive material and an electron donor whilst the zinc oxide acts as an electron acceptor. The doping according to the present invention improves the characteristics exhibited. The labels refer to: 31 vacuum; 32 a label indicating that an empty circle in the diagram is an electron; 33 a label indicating that a filled circle in the diagram is a hole; 34 is a photon; 35 is a label for the LUMO (4.4 eV) and HOMO (7.6 eV) of the ZnO; and 36 is a label for the LUMO (4 eV) and HOMO (5.8 eV) of the PbO.

FIG. 4 is a scanning electron micrograph (SEM) of the photosensitive layer (film) edge of the present invention taken at 45° to the top surface.

FIG. 5 shows:
a) TEM micrograph showing an ensemble of lead oxide nanoparticles (scale bar is 20 nm);
b) High resolution micrograph of a nanoparticle (scale bar is 2 nm);
c) Fast Fourier Transform (FFT) of b, indexed according the Minium structure;
d) Proposed structure of Pb(IV)Pb(II)₂O₄ projected on the a,b plane (the plane circles are Pb(IV), the hatched are Pb(II) and the spotted are O).

FIG. 6 shows the Current-voltage characteristics of a device according to the present invention under 100 mW cm⁻² AM1.5 Illumination. The Y axis is Current in mA cm⁻². The X axis is Voltage (V). 61 is In bottom doped and 62 is Sb top doped.

FIG. 7 shows the absorption and IPCE (internal photon conversion efficiency) of a photosensitive layer of a device according to the present invention. The left-hand Y axis is IPCE (%). The right-hand Y axis is absorption (au). The X axis is wavelength (nm). 71 is the IPCA trace and 72 is the absorption trace.

### EXAMPLES

The invention will now be shown in the following non-limiting example.

Devices were fabricated as follows, ITO coated glass substrates (PGO, CEC005, ≦5 Ohms/sq.) were etched in a solution of H₂O, HCl and HNO₃ (25:25:2 vol) at 50° C. for 8 minutes. The substrates were then sonicated in detergent solution and deionised water before being washed in acetone and isopropyl alcohol. The substrates were then dried at ambient temperature in a nitrogen glovebox (≦1 ppm O₂, ≦2 ppm H₂O) overnight. Substrates were transferred to a vacuum chamber where the following was deposited at a base pressure of 2.5×10-7 torr:

1. 5-10 nm of indium followed by 120 nm of lead.

2. 120 nm of lead followed by 5-10 nm Antimony

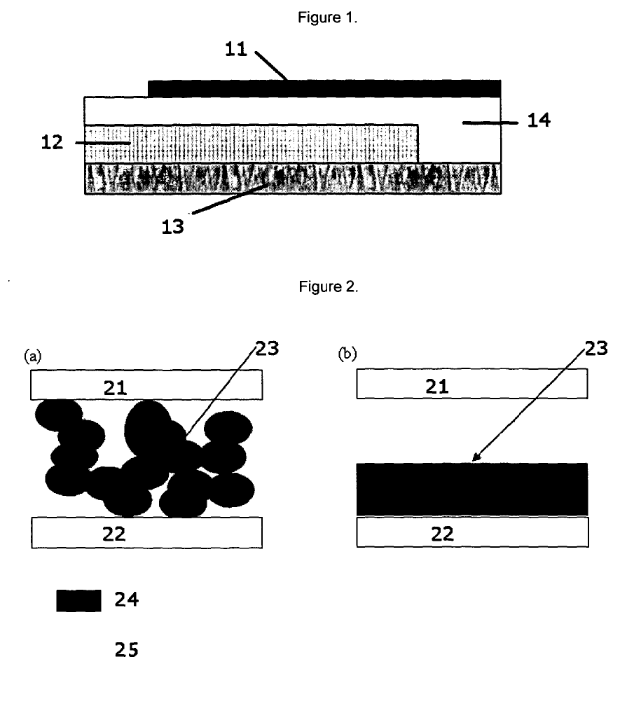

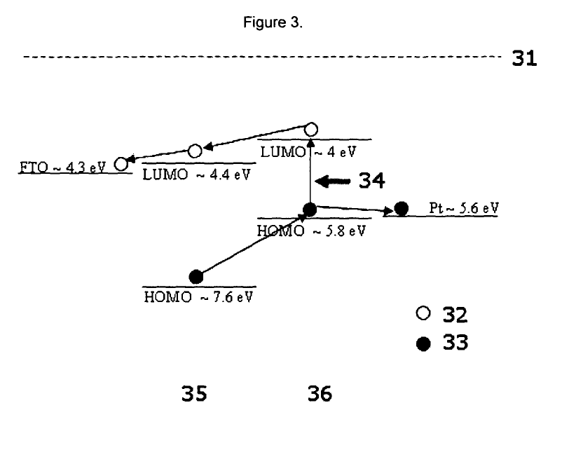

The films where then placed on a hotplate outside the glovebox and annealed for one hour at 350° C. in which time they turned from shiny black to an opaque yellow-brown. Each device had an area of 3 mm². Substrates were then transferred back to the vacuum chamber where Al electrodes (70 nm) were deposited at a pressure of 2.5×10-7 torr. The device geometry is shown in FIG. 1.

Scanning electron microscopy was performed on a JEOL JSM-840F microscope at an accelerating voltage of 10 kV. Samples were prepared by attaching a cleaved device to a metal stub and depositing 3 nm of platinum on top.

Transmission electron microscopy was performed on a JEOL-JEM 2010 LaB6 microscope at an accelerating voltage of 200 kV equipped with an Oxford Instruments LZ5 windowless energy dispersive X-ray spectrometer (EDS) controlled by INCA.

Samples were prepared as follows. Part of the device active layer was scrapped off its substrate using a scalpel, and sonicated in isopropanol for 3 minutes to break up the composite into a micron size dispersion which could be drop-cast onto lacy carbon film-coated copper grids. A sufficient number of flakes adhered to the TEM grid and overhung holes in the lacy carbon film to allow TEM analysis.

Current density-voltage (IV) curves were determined using a Oriel solar simulator (80 mW cm⁻²) fitted with an AM1.5G filter) and a Keithley 2400 SMU. The light intensity at the sample position was determined with a microprocessor-based power meter (Thermo-Oriel Instruments, Model No. 70260) calibrated according to ASTM standards. Absorption spectroscopy measurements were performed using a Varian Cary 5000i UV-VIS-NIR spectrometer. Quantum efficiencies were measured using a Keithley 6435 picoammeter CVI CM110 monochromator and CVI 150 W arc lamp. All incident light intensities were measured using a NIST calibrated silicon detector.

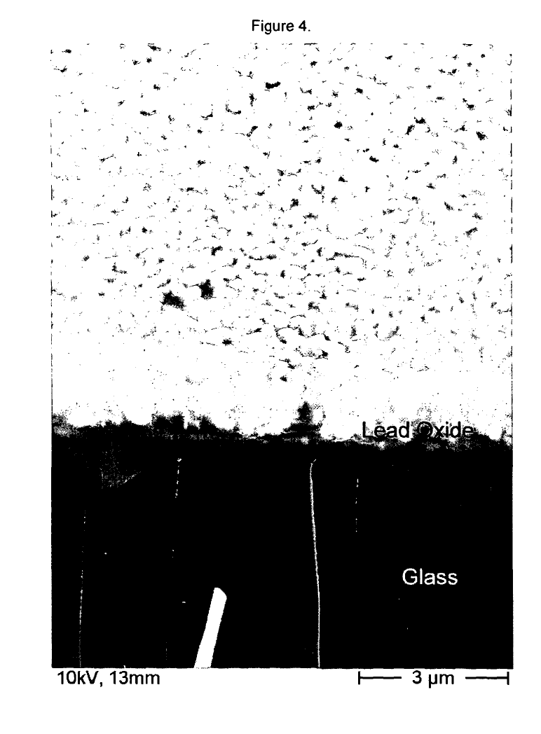

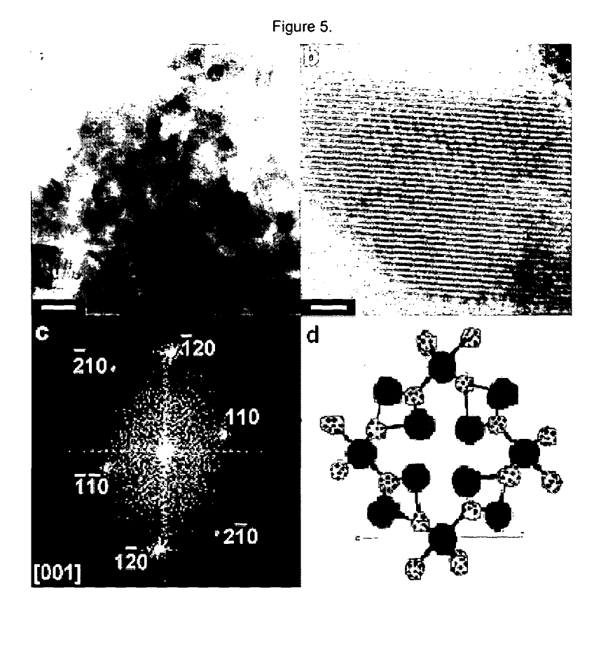

The post thermal oxidisation lead oxide films where first analysed using SEM (FIG. 4) and showed that a rough continuous film which is to some extent porous was formed. This is obviously not ideal for thin-film photovoltaics where ultra flat thin-films are key to high efficiencies in second generation photovoltaics. TEM investigation of the photoactive material provides insight into its morphology and structure.

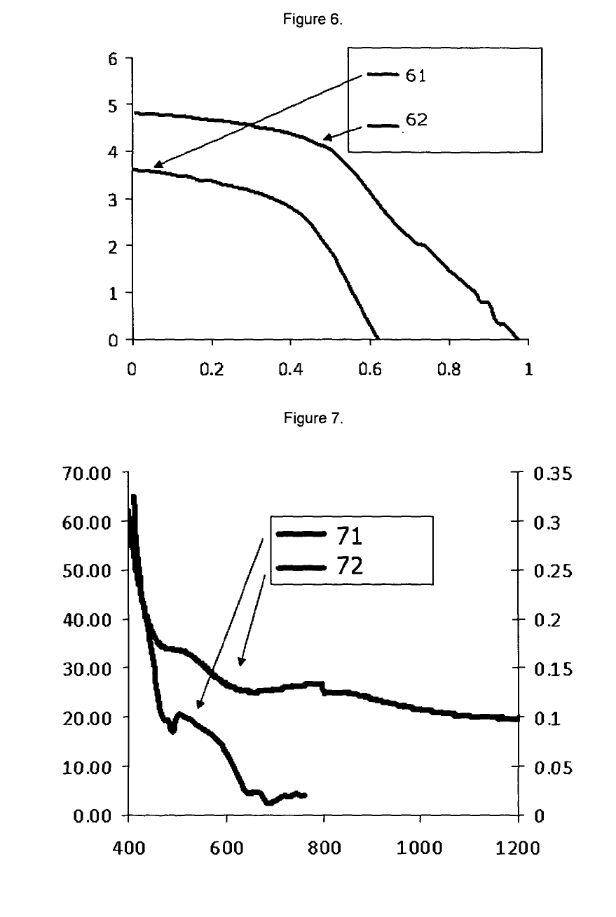

The material is polycrystalline as evident from the low resolution TEM micrograph of FIG. 5 (a). The grain size is in the nanoscale range, in the order of a few tens of nanometers. The fringes shown in FIG. 5 (a) are Moiré fringes caused by the overlapping of different nanocrystalline grains across the projection of the image plane. In order to study the structure of the material we conducted high resolution TEM imaging of the individual grains. FIG. 5(b) is a high resolution micrograph of a nanoparticle (scale bar is 2 nm). The inter-plane spacing and angle are determined from the two dimensional fast Fourier transform shown in FIG. 5(c) and show that the crystal is Pb(IV)Pb(II)₂O₄—an oxide also known as Minium (Pb₃O₄). A model of the Minium structure as projected on the a,b plane is shown in FIG. 5(d) with the 4-valence lead atoms (plane spheres) and 2-valence lead atoms (hatched). EDX shown (FIG. 6) is used to show that lead oxide is the main component.

The best devices produced have open circuit voltages of 0.97 V, short circuit currents of 4.85 mA cm⁻² and power conversion efficiencies of 1.6%. These efficiencies prove that the photovoltaic response is definite and considering the roughness of the film surprisingly good.

Device results are shown in FIG. 6 and summarised in Table 1. The Sb doped sample will have some doping at the ITO interface due to Indium migration from the substrate. Efficiencies are expected to improve substantially with a more controlled doping profile.

TABLE 1
Device results summary

| | In bottom doped | Sb top doped |
|---|---|---|
| Voc (V) | 0.62 | 0.97 |
| Isc (mA cm−2) | 3.63 | 4.85 |
| PCE (%) | 0.93 | 1.6 |

Internal photon conversion efficiency (IPCE) and absorption results are shown in FIG. 7. Unfortunately the IPCE does not extend beyond 700 nm, however absorption shows a broad band response which is useful for photovoltaic application, and this may be attributed to polymorphic PbO impurities.

When researching any technology for any application it is important to consider whether technological benefit outweighs the risk involved. Compared to other comparable systems, such as CdTe, PbO is much less toxic.

1. A solar cell comprising an anode and a cathode with a photosensitive layer therebetween, wherein the photosensitive layer is at most 1000 nm thick and comprises crystalline lead oxide as a photosensitive material, wherein the lead oxide is doped with antimony and/or indium.

2. A solar cell according to claim 1, wherein the lead oxide is of the formula Pb₁₋ₓSb_{y}O,
Pb₁₋ₓIn_{z}O, or Pb₁₋ₓSb_{y′}In_{z′}O, wherein x, y, z and (y′+z′) are independently from 0.01 to 0.5.

3. A solar cell according to claim 2, wherein x, y, z and (y′+z′) are independently from 0.01 to 0.3, more preferably from 0.01 to 0.2.

4. A solar cell according to claim 1, wherein the ratio of x to y, z or (y′+z′) is from 0.75 to 1.25.

5. A solar cell according to claim 1, wherein the photosensitive layer comprises at least one further metal oxide selected from a zinc oxide and/or a titanium oxide.

6. A solar cell according to claim 5, wherein in the photosensitive layer the lead oxide is mixed with and interpenetrates the at least one further metal oxide.

7. A solar cell according to claim 5, wherein the ratio of the lead oxide to the at least one further metal oxide is from 20:1 to 1:20.

8. A solar cell according to claim 1, wherein the photosensitive layer comprises a discrete doped lead oxide layer.

9. A solar cell according to claim 8, wherein the lead oxide layer is formed directly on the anode.

10. A solar cell according to claim 1, wherein the photosensitive layer has a thickness of 500 nm or less.

11. A solar cell according to claim 1, wherein the crystalline lead oxide is polycrystalline and has a mean crystal diameter of from 1 to 1000 nm, preferably from 10 to 500 nm.

12. A solar cell according to claim 1, wherein the lead oxide essentially comprises doped Minium (Pb₃O₄).

13. A solar cell according to claim 1, wherein one of the anode and the cathode is substantially transparent to visible light and preferably comprises a doped metal oxide.

14. A solar cell according to claim 13, wherein the doped metal oxide is aluminium doped zinc oxide and/or indium tin oxide.

15. A solar cell according to claim 1, wherein at least one of the anode and the cathode comprises aluminium, platinum, gold, palladium, copper or silver, or an alloy comprising any thereof.

16. A solar cell according to claim 15, wherein at least one of the anode and the cathode is formed of aluminium.

17. A solar cell according to claim 1, wherein the crystalline lead oxide is polymorphic.

18. A process for manufacturing a solar cell comprising a first electrode, a photosensitive layer and a second electrode, said process comprising:
providing a first electrode having a surface;
forming a photosensitive layer on the surface of the first electrode that is at most 1000 nm thick and comprises crystalline lead oxide, doped with indium and/or antimony, as a photosensitive material; and
providing a second electrode thereon.

19. A process according to claim 18, wherein the photosensitive layer is formed by providing a precursor layer of lead and one or both of indium and antimony on a surface of the first electrode and then contacting the precursor layer with a source of oxygen.

20. A process according to claim 18, wherein the photosensitive layer is formed by vapour deposition, electrodeposition, thermal evaporation, ion plating, reactive sputtering or the application of a sol-gel/colloidal nanoparticle paint.

21-25. (canceled)
